(19) United States
(12) Patent Application Publication
(10) Pub. No.: US 2002/0172229 A1
(43) Pub. Date: Nov. 21, 2002

(54) Method and apparatus for transporting a synchronous or plesiochronous signal over a packet network

(75) Inventors: Davar Parvin, Southington, CT (US); John M. O'Neil, Litchfield, CT (US); Joseph P. Hickey, Naugatuck, CT (US)

Correspondence Address: David P. Gordon, Esq., 65 Woods End Road, Stamford, CT, 06905, US

(73) Assignee: Kenetec, Inc.

(21) Appl. No.: 10/003,623

(22) Filed: Nov. 2, 2001

Related U.S. Application Data
(60) Provisional application No. 60/276,630, filed on Mar. 16, 2001.

(51) Int. Cl. H04J 3/00

(52) U.S. Cl. 370/521; 370/419

(57) ABSTRACT

Methods and apparatus for transporting a synchronous or plesiochronous signal over a packet network. The methods of the invention include providing incoming and outgoing packet counters at the “local” user-network-interface (UNI) where the packets are to be reassembled into a synchronous or plesiochronous signal. According to the basic method of the invention, the UNI is provided with an adjustable clock and the clock rate is adjusted by comparing the incoming packet count with the outgoing packet count. In particular, if the outgoing packet count is smaller than the incoming packet count, the clock rate is increased. If the outgoing packet count is larger than the incoming packet count, the clock rate is decreased. In order to minimize delay in clock adjustments, a “gear shift” adjustment algorithm is provided. The apparatus of the invention includes a phase locked loop (PLL) embodied in a programmable logic device (PLD).

This application claims the benefit of co-owned, co-pending, provisional application serial No. 60/276,630 filed Mar. 16, 2001, entitled “Methods and Apparatus for Delivering Multimedia Communications Services to Multiple Tenants in a Building,” the complete disclosure of which is hereby incorporated by reference herein.

### BACKGROUND OF THE INVENTION

1. Field of the Invention

The invention relates to telecommunications. More particularly, the invention relates to clock recovery when transporting a synchronous or plesiochronous signal over a packet network.

2. State of the Art

The first commercial digital voice communications system was installed in 1962 in Chicago, Ill. The system was called “T1” and was based on the time division multiplexing (TDM) of twenty-four telephone calls on two twisted wire pairs. The digital bit rate of the T1 system was 1.544 Mbit/sec (±200 bps), which was, in the nineteen sixties, about the highest data rate that could be supported by a twisted wire pair for a distance of approximately one mile. The cables carrying the T1 signals were buried underground and were accessible via manholes, which were, at that time in Chicago, spaced approximately one mile apart. Thus, analog amplifiers with digital repeaters were conveniently located at intervals of approximately one mile.

The T1 system is still widely used today and forms a basic building block for higher capacity communication systems including T3 which transports twenty-eight T1 signals. The designation T1 was originally coined to describe a particular type of carrier equipment. Today T1 is often used to refer to a carrier system, a data rate, and various multiplexing and framing conventions. While it is more accurate to use the designation “DS1” when referring to the multiplexed digital signal carried by the T1 carrier, the designations DS1 and T1 are often used interchangeably. Today, T1/DS1 systems still have a data rate of 1.544 Mbit/sec and support typically twenty-four voice and/or data DS0 channels. Similarly, the designations DS2 and T2 both refer to a system transporting up to four DS1 signals (96 DS0 channels) and the designations DS3 and T3 both refer to a system transporting up to seven DS2 signals (672 DS0 channels). The timing tolerance for modern T1 equipment has been raised to ±50 bps. T1 signals are said to be “plesiochronous” (nearly synchronous). Clock variations at nodes are corrected by line codes such as alternate mark inversion (AMI or bipolar line code). These codes set up patterns in the bitstream of the signal which are used at nodes to correct for clock variations.

Today, another higher bandwidth TDM system is in use. This system is referred to as the synchronous optical network (SONET) or, in Europe, the synchronous digital hierarchy (SDH). Unlike plesiochronous signals, SONET signals are synchronized to a master network clock. Although the timing of SONET signals is very accurate, some clock variations still exist at different nodes in the network. Various complex techniques are provided to correct for clock differences at different nodes.

The T1 and T3 networks were originally designed for digital voice communication. In a voice network minor bit errors can be tolerated as a small amount of noise. However, in a data network, a minor bit error cannot be tolerated. In the early 1970s, another technology was deployed to support data networks. The technology was called “packet switching”. Unlike the T1 and T3 networks, packet switching was designed for data communications only. In packet switching, a “packet” of data includes a header, a payload, and a cyclic redundancy check (CRC). The header includes addressing information as well as an indication of the length of the payload. The payload contains the actual data which is being transmitted over the network. The CRC is used for error detection. The receiver of the packet performs a calculation with the bits in the packet and compares the result of the calculation to the CRC value. If the CRC value is not the same as the result of the calculation, it means that the packet was damaged in transit. According to the packet switching scheme, the damaged packet is discarded and the receiver sends a message to the transmitter to resend the packet. One popular packet switching scheme for wide area networks (WANs), known as X.25, utilizes a packet which has a fixed payload of 128 octets. Other packet switching schemes allow variable length packets up to 2,000 octets. Frame Relay is an example of a WAN packet switching scheme which utilizes variable sized packets and Ethernet is an example of a local area network (LAN) packet switching scheme which utilizes variable sized packets. Packet switching networks are asynchronous and, by design, are not well suited for the transmission of a streaming signal such as voice or video. If streaming voice or video is transmitted via packets, small amounts of noise in the signal will result in discontinuity of the stream, echo, and other problems.

Concurrent with the development of packet switching several groups around the world began to consider standards for the interconnection of computer networks and coined the term “internetworking”. The leading pioneers in internetworking were the founders of ARPANET (the Advanced Research Projects Network). ARPA, a U.S. Department of Defense organization, developed and implemented the transmission control protocol (TCP) and the internet protocol (IP). The TCP/IP code was dedicated to the public domain and was rapidly adopted by universities, private companies, and research centers around the world. An important feature of IP is that it allows fragmentation operations, i.e. the segmentation of packets into smaller units. This is essential to allow networks which utilize large packets to be coupled to networks which utilize smaller packets. Today, TCP/IP is the foundation of the Internet. It is used for email, file transfer, and for browsing the Worldwide Web. It is so popular that many organizations are hoping to make it the worldwide network for all types of communication, including voice and video.

Perhaps the most awaited, and now fastest growing technology in the field of telecommunications is known as Asynchronous Transfer Mode (ATM) technology. ATM was originally conceived as a carrier of integrated traffic, e.g. voice, data, and video. ATM utilizes fixed length packets (called “cells”) of 53 octets (5 octets header and 48 octets payload). ATM may be implemented in either a LAN or a WAN. For ideal data transfer, ATM is used end to end from the data source to the data receiver.

Current ATM service is offered in different categories according to a user's needs. Some of these categories include constant bit rate (CBR), variable bit rate (VBR), unspecified bit rate (UBR), and available bit rate (ABR). CBR service is given a high priority and is used for streaming data such as voice and video where a loss of cells would cause a noticeable degradation of the stream. UBR and ABR services are given a low priority and are used for data transfers such as email, file transfer, and web browsing where sudden loss of bandwidth (bursty bandwidth) can be tolerated. ATM service is sometimes referred to as “statistical multiplexing” as it attempts to free up bandwidth which is not needed by an idle connection for use by another connection.

ATM switches (like other packet switches) typically include multiple buffers, queues, or FIFOs for managing the flow of ATM cells through the switch. Generally, a separate buffer is provided for each outlet from the switch. However, it is also known to have separate buffers at the inlets to the switch. Buffer thresholds are set to prevent buffer overflow. If the number of cells in a buffer exceeds the threshold, no more cells are allowed to enter the buffer. Cells attempting to enter a buffer which has reached its threshold will be discarded.

Whenever a synchronous or plesiochronous signal is transmitted over a packet network, e.g. ATM or the Internet, the originating clock must be recovered at the receiver. Clock recovery is necessary to prevent excessive packet loss, to prevent unacceptable delay in processing the signal, and, in the case of TDM signals, to facilitate framing. One method of recovering a clock signal, called adaptive clock recovery, involves measuring the depth of a (jitter) buffer. If the buffer depth is greater than a maximum threshold or is increasing with time, the local clock rate is increased to cause the buffer to drain more quickly. If the buffer depth is less than a minimum threshold or is decreasing with time, the local clock rate is decreased to cause the buffer to drain less quickly. The main drawback of this clock recovery method is that following an adjustment of the clock rate, there is a delay before the buffer depth stabilizes due to the inertia of the buffer depth. This delay may cause instability or excessive jitter in the recovered clock.

In January 1997, the ATM forum defined “Circuit Emulation Service” (CES) as af-vtoa-0078.000. CES uses ATM AAL1 adaptation to segment incoming E1 or T1 traffic into ATM cells with the necessary timing information to ensure that the circuit can be correctly reassembled at the destination. The timing information is provided in the ATM cell headers and is referred to as the synchronous residual time stamp (SRTS). The time stamp is used by the receiver to determine the difference between a common reference clock and the sender's local clock. SRTS assumes the availability of a common synchronous network clock from which the sender and receiver can both reference. It also assumes that the T1/E1 signal enters an ATM network and remains in the ATM network until it exits as a T1/E1 signal. If the signal passes through other networks (e.g. IP networks or Ethernet networks) and loses traceability to the common reference clock, SRTS fails. For example, the previously incorporated co-owned application describes a system in which ATM cells containing packetized T1/E1 signals are transported over Ethernet. The Ethernet receiver cannot utilize SRTS to recover the clock of T1/E1 signals.

### SUMMARY OF THE INVENTION

It is therefore an object of the invention to provide methods and apparatus for transporting a synchronous or plesiochronous signal over a packet network.

It is also an object of the invention to provide methods and apparatus which do not rely on a common synchronous network clock for transporting a synchronous or plesiochronous signal over a packet network.

It is another object of the invention to provide methods for transporting a synchronous or plesiochronous signal over a packet network which do not suffer the disadvantages of prior art adaptive clock recovery methods.

It is still another object of the invention to provide methods and apparatus for transporting a synchronous or plesiochronous signal over a packet network which operates over any type of packet network including a hybrid network which combines different types of packet switching between source and destination.

In accord with these objects which will be discussed in detail below, the methods and apparatus of the present invention are exemplified with reference to a network in which a T1 signal has been segmented into ATM AAL1 cells. The methods of the invention include providing incoming and outgoing cell counters at the “local” user-network-interface (UNI) where the AAL1 cells are to be reassembled into a T1 signal. The invention is implemented under two assumptions. The first assumption is that the “remote” network-network-interface (NNI) receives and transmits AAL1 packets at a consistent rate. The second assumption is that when the local UNI clock and remote NNI clock are locked, the number of cells received at the UNI should increase at the same rate as the number of cells transmitted by the UNI. According to the basic method of the invention, the UNI is provided with an adjustable clock and the clock rate is adjusted by comparing the incoming cell count with the outgoing cell count. In particular, if the outgoing cell count is smaller than the incoming cell count, the clock rate is increased. If the outgoing cell count is larger than the incoming cell count, the clock rate is decreased. In order to minimize delay in clock adjustments, a “gear shift” adjustment algorithm is provided. In the presently preferred embodiment, four different levels of adjustment are provided, level 3 being the coarsest (fastest) and level 0 being the finest (slowest).

The apparatus of the invention includes a phase locked loop (PLL) embodied in a programmable logic device (PLD). The apparatus has run-time clock adjustment capabilities. According to the presently preferred embodiment, the CPU performing AAL1 processing dynamically adjusts its own clock by reading a register in the PLD. The register is referred to as CLKADJ and the value written to it by the PLL is an absolute number of clock ticks to add or subtract per million. The cell counters are preferably implemented as 16-bit unsigned integer counters. The transmit cell counter is incremented whenever a cell is sent to the NNI from the UNI and the receive cell counter is incremented whenever a cell is added to the receive buffer in the UNI. The cell counters are modulo-65536 counters which wrap to zero and continue to count up from 1.

To allow for network jitter and the relatively slow drift rate of the cell counters in the presently preferred implementation, the PLL routine is run at relatively long intervals, e.g 2048 ms. The interval can be adjusted for different applications. The PLL routine begins by computing the difference between the receive cell counter and the transmit cell counter. According to one embodiment, the difference is written to the register CLKADJ. Thus, if, e.g., the UNI has received one more cell than it has transmitted, the value 1 will be written to CLKADJ. This will cause the local clock rate to be increased by one tick per million. As mentioned above, in order to decrease the convergence time of the PLL, the preferred embodiment of the invention utilizes a “gear shift” algorithm. According to the presently preferred embodiment, the value in the register CLKADJ is magnified by a factor of 2^{Level} where 0≦Level≦3. When Level=3, the PLL will approach the correct frequency very quickly and will eventually begin to “circle” the true frequency. According to the “gear shift” algorithm of the invention, when circling is detected, Level is lowered to 2, then 1 and then 0. According to the presently preferred embodiment, circling is detected by taking the derivative of the CLKADJ value and detecting sign changes in the derivative. After the derivative changes sign several times, circling is detected and the level is decreased. When the level reaches 0 it is no longer changed.

Additional objects and advantages of the invention will become apparent to those skilled in the art upon reference to the detailed description taken in conjunction with the provided figures.

### BRIEF DESCRIPTION OF THE DRAWINGS

FIG. 1 is a simplified block diagram of a system incorporating the invention;

FIG. 2 is a simplified block diagram of portions of the UNI according to the invention;

FIG. 3 is a flow chart illustrating a first method of the invention; and

FIG. 4 is a flow chart illustrating a second method of the invention.

### DETAILED DESCRIPTION OF THE PREFERRED EMBODIMENTS

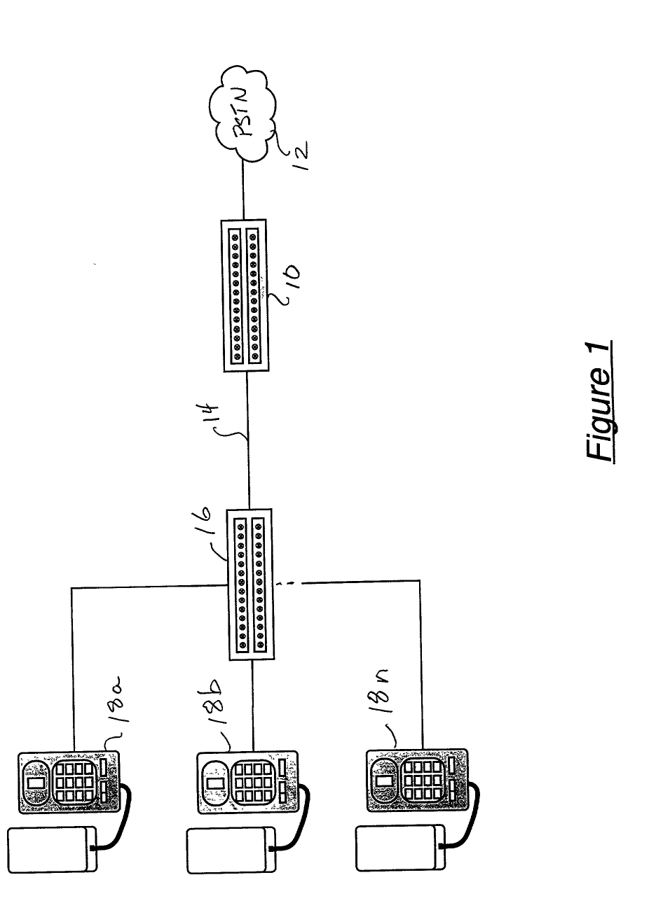

Referring now to FIG. 1, an apparatus incorporating the invention generally includes a network-network-interface NNI 10 which is coupled to the PSTN 12 and to an Ethernet LAN 14, and at least one user-network interface UNI 16 which is coupled to the LAN 14 and a plurality of user devices such as telephones 18a, 18b, . . . 18n. The LAN 14 is a packet network and is substantially the same as the LAN described in the previously incorporated co-owned, co-pending provisional application wherein ATM cells containing packetized T1/E1 signals are transmitted over an Ethernet LAN.

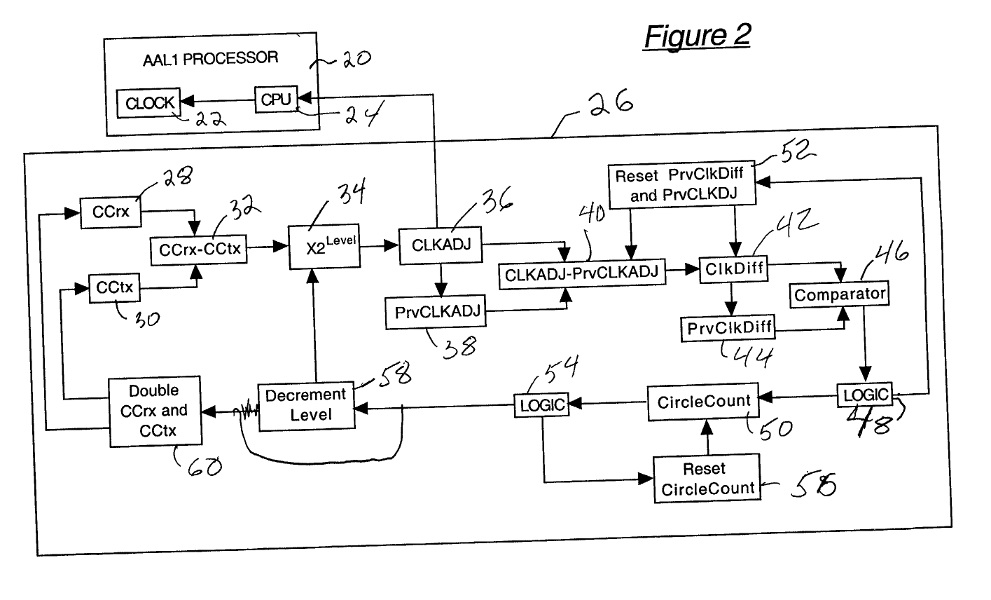

According to the invention, the UNI 16 includes an AAL1 processor as well as an apparatus for recovering the clock rate of a synchronous or plesiochronous signal carried from the PSTN over the packet LAN 14 via the NNI 10. Turning now to FIG. 2, the AAL1 processor 20 includes a clock generator 22 and a CPU 24. The CPU 24 performs the AAL1 processing and controls the clock generator 22 by adding or removing a number of clock ticks per million. The UNI is further provided with a programmable logic device (PLD) 26 for implementing a phase locked loop (PLL) to provide the CPU 24 with a clock tick number to adjust the CLOCK 22. The PLD 26 includes a number of counters, registers, arithmetic processes and logical processes. More particularly, the PLD 26 includes a received cell counter (CCrx) 28, a transmitted cell counter (CCtx) 30, a subtractor 32 for subtracting the number of transmitted cells from the number of received cells (CCrx−CCtx), and a multiplier 34 for multiplying the difference (CCrx−CCtx) times 2^{Level}, where “Level” is an integer from zero to three.

The result of the computation (CCrx−CCtx)×2^{Level} is stored in a register 36 called CLKADJ. The number written in CLKADJ is an absolute number of clock ticks per million for the CPU 24 to add to the clock generator 22. The cell counters 28, 30 are preferably implemented as 16-bit unsigned counters. The transmit cell counter CCtx is incremented whenever a cell is sent to the NNI (10 in FIG. 1) from the UNI (16 in FIG. 1) and the receive cell counter CCrx is incremented whenever a cell is added to the receive buffer (not shown) in the UNI. The cell counters are modulo-65536 counters which wrap to zero and continue to count up from 1. To allow for network jitter and the relatively slow drift rate of the cell counters in the presently preferred implementation, the calculation of CLKADJ is performed every 2048 ms. The interval can be adjusted for different applications. The method and apparatus described thus far provides a simple PLL based on the relative number of transmitted and received cells. As mentioned above, however, this simple PLL may take a long time lock.

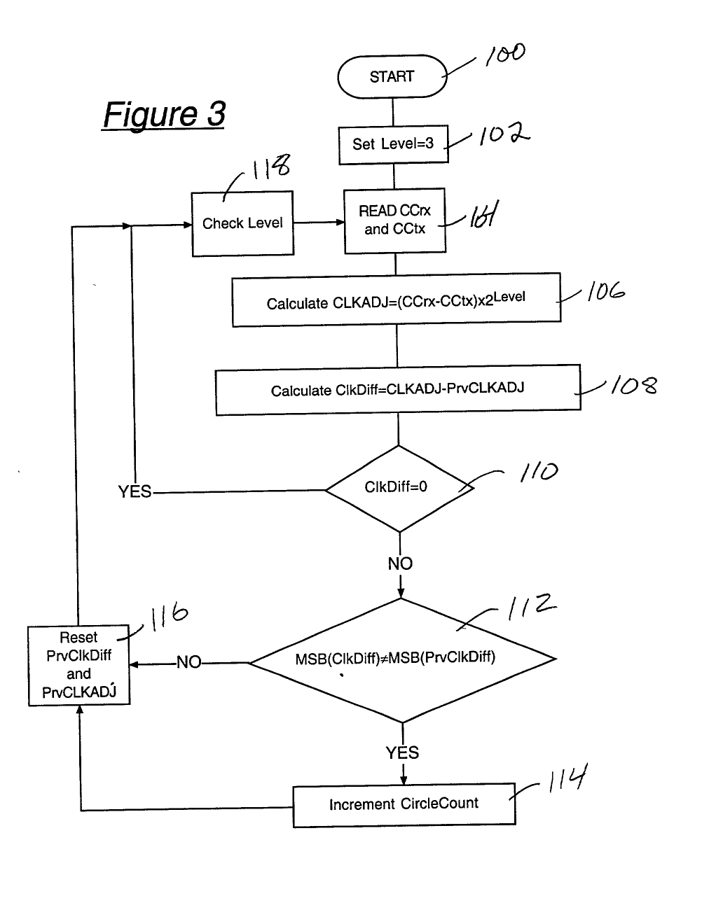

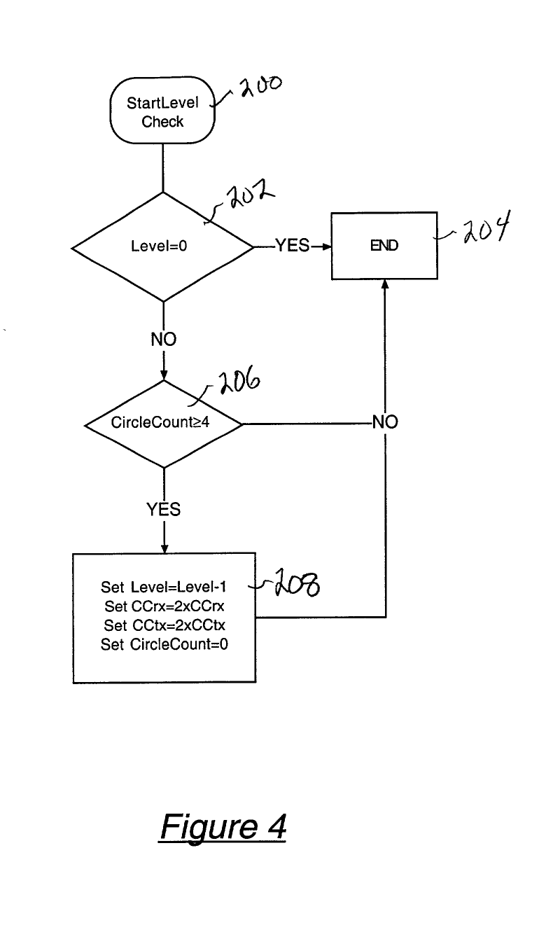

According to the preferred embodiment of the invention, a “gear shift” routine is also run each time CLKADJ is recomputed. The remainder of the blocks in FIG. 2 are used to implement the gear shift routine which shifts the value of Level from an initial value of three to a locked value of zero. These additional components include a register 38 for storing the last previous value “PrvCLKADJ” of CLKADJ, a subtractor 40 for determining the change “ClkDiff” in CLKADJ by calculating (CLKADJ−PrvCLKADJ), a register 42 for storing the calculated ClkDiff, and a register 44 for storing the previous value “PrvClkDiff” of ClkDiff. A comparator 46 is provided for comparing ClkDiff and PrvClkDiff. Based on the comparison, logic 48 may increment a circle counter 50 and/or trigger the reset 52 of PrvCLKADJ and PrvClkDiff. Logic 54 monitors the circle counter 50. When the circlecount has reached a threshold, logic 54 triggers the reset 56, level decrementer 58, and cell count doubler 60. The operation of the components in FIG. 2 are better understood by reference to the complete PLL and gear shift routine which is illustrated in FIGS. 3 and 4.

Turning now to FIG. 3, the operation of the invention begins at 100 when a connection is established. The exponent “Level” is set to “3” at 102. The cell counters are read at 104 and CLKADJ and ClkDiff are calculated at 106 and 108 respectively. If it is determined at 110 that the ClkDiff is zero, the routine returns to check the value of Level at 118, read the cell counters at 104, and recalculate CLKADJ and ClkDiff. As mentioned above, the calculation of CLKADJ and ClkDiff is performed approximately every two seconds, e.g 2048 ms, thus, there will be a delay between 118 and 104 in the flow chart of FIG. 3. It will be appreciated that the first iteration of this method will result in no ClkDiff which will be treated as ClkDiff=0. If the ClkDiff is not zero, the most significant bit (MSB), i.e. the sign ±, of ClkDiff is compared to the MSB of PrvClkDiff at 112. If the signs are different it means that the CLKADJ is “circling” the correct adjustment value, i.e. moving up and down about the correct value. In this case, the circle counter is incremented at 114. In either case, the PrvClkDiff and PrvCLKADJ are reset to ClkDiff and CLKADJ, respectively at 116.

The components for performing the method of FIG. 3 are shown in FIG. 2 as the logic 48, the CircleCount register 50, and the reset block 52. Before resuming the next iteration of the method of FIG. 3 at 104, the value of Level is checked at 118. The “Level Check” algorithm also includes a Level adjustment method which is illustrated in FIG. 4.

Entering FIG. 4 from block 118 in FIG. 3, the Level Check starts at 200. If it is determined at 202 that Level=0, no further processing is needed and the routine returns at 204 to block 104 in FIG. 3. If Level≠0, it is determined at 206 whether the circlecount≧4. If it is not, the routine returns at 204. If it is, a number of operations are performed at 208 before returning at 204 to block 104 in FIG. 3. The first operation is that the value of Level is decremented by one. It will be appreciated that this is performed by the component 58 in FIG. 2. The next operation is that the values of the cell counters are doubled. This is performed by the component 60 in FIG. 2. This is done only once at each level decrement to smooth the transition from one level to the next. The last operation is the resetting of the CircleCount to zero which is performed by the component 56 in FIG. 2.

Exemplary pseudocode for performing the method of FIG. 3 is listed below.

CLKADJ= (CCrx−CCtx<<Level;
If (CLKADJ−PrvCLKADJ!=0)

Then

ClkDiff=CLKADJ−PrvCLKADJ;
If ((ClkDiffPrvClkDiff)&0x8000)

Then

CircleCount++;

End If

PrvClkDiff=ClkDiff;
PrvCLKADJ=CLKADJ;

End If

Exemplary pseudocode for performing the method of FIG. 4 is listed below.

If (CircleCount>=4&&Level>0

Then

Level=Level−1;
CCrx=CCrx<<1;
CCtx=CCtx<<1;
CircleCount=0;

End If

The methods and apparatus of the invention include providing incoming and outgoing cell counters at the “local” user-network-interface (UNI) and using these counters to reconstruct the clock at the network-network-interface (NNI). According to the basic method of the invention, the UNI is provided with an adjustable clock and the clock rate is adjusted by comparing the incoming cell count with the outgoing cell count. In particular, if the outgoing cell count is smaller than the incoming cell count, the clock rate is increased. If the outgoing cell count is larger than the incoming cell count, the clock rate is decreased. In order to minimize delay in clock adjustments, a “gear shift” adjustment algorithm is provided. In the presently preferred embodiment, four different levels of adjustment are provided, level 3 being the coarsest (fastest) and level 0 being the finest (slowest).

There have been described and illustrated herein methods and apparatus for transporting a synchronous or plesiochronous signal over a packet network. While particular embodiments of the invention have been described, it is not intended that the invention be limited thereto, as it is intended that the invention be as broad in scope as the art will allow and that the specification be read likewise. Thus, while particular hardware and software have been disclosed, it will be appreciated that other hardware and/or software could be utilized. Also, while certain level values and circle count values have been shown, it will be recognized that other values could be used with similar results obtained depending on the application. Moreover, while particular examples have been disclosed in reference to ATM, Ethernet, and T1/E1 signals, it will be appreciated that the invention is applicable to any packet switching network carrying packetized synchronous or plesiochronous signals. Thus, while the disclosure refers to AAL1 and “cell counters”, when applied to another packet network, “packet counters” will be used and another packetizing scheme other than AAL1 will be used. It will therefore be appreciated by those skilled in the art that yet other modifications could be made to the provided invention without deviating from its spirit and scope as so claimed.

1. An apparatus for transporting a synchronous or plesiochronous signal over a packet network, comprising:
a) a packet processor having an adjustable clock generator;
b) a received packet counter generating a received packet count;
c) a transmitted packet counter generating a transmitted packet count; and
d) a clock adjustment means coupled to said adjustable clock generator, said received packet counter, and said transmitted packet counter, such that said adjustable clock generator is adjusted to a higher rate when said transmitted packet count is smaller than said received packet count.

2. An apparatus according to claim 1, wherein:
said clock adjustment means includes
subtraction means coupled to said received packet counter and said transmitted packet counter for subtracting said transmitted packet count from said received packet count, and
register means for storing the difference calculated by said subtraction means,
said adjustable clock generator being adjusted an amount proportional to said difference.

3. An apparatus according to claim 2, wherein:
said clock adjustment means includes multiplication means coupled to said subtraction means and said register means such that the difference calculated by said subtraction means is multiplied by said multiplication means before being stored in said register means.

4. An apparatus according to claim 3, wherein:
said multiplication means is adjustable.

5. An apparatus according to claim 4. wherein:
said multiplication means multiplies the difference calculated by said subtraction means by 2ⁿ where n is adjustable.

6. An apparatus according to claim 5, wherein:
n is adjustable to an integer value from 3 to 0.

7. An apparatus according to claim 5, wherein:
said clock adjustment means includes derivative means coupled to said register means for detecting change in the difference calculated by said subtraction means, said derivative means having an output indicating the change in the difference calculated by said subtraction means over time.

8. An apparatus according to claim 7, wherein:
said clock adjustment means includes
comparator means coupled to said derivative means for detecting a change in sign of the output of said derivative means, and
decrementer means coupled to said comparator means and said multiplication means such that n is decremented based on the change in sign of the output of said derivative means.

9. An apparatus according to claim 8, wherein:
n is decremented by 1 after a predetermined number of changes in sign of the output of said derivative means.

10. An apparatus according to claim 8, wherein:
said clock adjustment means includes doubler means coupled to said received packet counter and said transmitted packet counter, such that said received packet count and said transmitted packet count are doubled each time n is decremented.

11. A method for transporting a synchronous or plesiochronous signal over a packet network, comprising:
a) processing packets with an adjustable clock generator;
b) keeping a count of the number of received packets;
c) keeping a count of the number of transmitted packets; and
d) adjusting the adjustable clock generator to a higher rate when the number of transmitted packets is smaller than the number of received packets.

12. A method according to claim 11, wherein:
said step of adjusting includes
subtracting the transmitted packet count from the received packet count,
storing the difference calculated by the subtraction, and
adjusting the adjustable clock by an amount proportional to the difference.

13. A method according to claim 12, wherein:
said step of adjusting includes
multiplying the difference calculated by the subtraction before storing the difference.

14. A method according to claim 13, wherein:
said step of multiplying includes adjusting the multiplication factor.

15. A method according to claim 1. wherein:
said step of multiplying includes multiplying by 2ⁿ where n is adjustable.

16. A method according to claim 15, wherein:
n is adjusted to an integer value from 3 to 0.

17. A method according to claim 15, wherein:
said step of adjusting includes detecting change in the difference calculated by the subtraction.

18. A method according to claim 17, wherein:
said step of adjustment includes
detecting a change in sign of the change in the difference calculated by the subtraction, and
decrementing n based on the change in sign.

19. A method according to claim 18, wherein:
n is decremented by 1 after a predetermined number of changes in sign.

20. A method according to claim 18, wherein:
said step of adjusting includes doubling the received packet count and the transmitted packet count each time n is decremented.

21. An apparatus for providing a clock adjustment value in a user-network-interface to a packet network, comprising:
a) a received packet counter generating a received packet count;
b) a transmitted packet counter generating a transmitted packet count; and
d) a clock adjustment value calculator coupled to said received packet counter and said transmitted packet counter for calculating a clock adjustment value based on a comparison of the received packet count and the transmitted packet count.

22. An apparatus according to claim 21, wherein:
said clock adjustment value calculator includes
subtraction means coupled to said received packet counter and said transmitted packet counter for subtracting said transmitted packet count from said received packet count, and
register means for storing the difference calculated by said subtraction means,
said clock adjustment value being an amount proportional to said difference.

23. An apparatus according to claim 22, wherein:
said clock adjustment value calculator includes multiplication means coupled to said subtraction means and said register means such that the difference calculated by said subtraction means is multiplied by said multiplication means before being stored in said register means.

24. An apparatus according to claim 23, wherein:
said multiplication means is adjustable.

25. An apparatus according to claim 24. wherein:
said multiplication means multiplies the difference calculated by said subtraction means by 2ⁿ where n is adjustable.

26. An apparatus according to claim 25, wherein:
n is adjustable to an integer value from 3 to 0.

27. An apparatus according to claim 25, wherein:
said clock adjustment value calculator includes derivative means coupled to said register means for detecting change in the difference calculated by said subtraction means, said derivative means having an output indicating the change in the difference calculated by said subtraction means over time.

28. An apparatus according to claim 27, wherein:
said clock adjustment value calculator includes
comparator means coupled to said derivative means for detecting a change in sign of the output of said derivative means, and
decrementer means coupled to said comparator means and said multiplication means such that n is decremented based on the change in sign of the output of said derivative means.

29. An apparatus according to claim 28, wherein:
n is decremented by 1 after a predetermined number of changes in sign of the output of said derivative means.

30. An apparatus according to claim 28, wherein:
said clock adjustment value calculator includes doubler means coupled to said received packet counter and said transmitted packet counter, such that said received packet count and said transmitted packet count are doubled each time n is decremented.

31. An apparatus for adjusting the granularity of clock adjustments in an interface to a packet network, comprising:
a) a clock adjustment calculator for calculating a raw clock adjustment value based on the flow of packets into and out of the interface;
b) a clock adjustment magnifier coupled to said clock adjustment calculator for magnifying said raw clock adjustment value by an adjustable factor to provide an actual clock adjustment value;
c) first comparison means for comparing a current clock adjustment value with a previous clock adjustment value to provide a clock difference value;
d) magnifier adjustment means coupled to said clock adjustment magnifier and to said first comparison means for adjusting said adjustable factor based on comparisons of clock adjustment values.

32. An apparatus according to claim 31, wherein:
said magnifier adjustment means is a first derivative means for determining the rate of change in clock adjustment values over time.
